(19) United States
(12) Patent Application Publication
(10) Pub. No.: US 2026/0211054 A1
(43) Pub. Date: Jul. 23, 2026

(54) METHOD AND APPARATUS FOR SORTING OUT DEFECTIVE BATTERY CELLS

(71) Applicant: SK On Co., Ltd., Seoul (KR)

(72) Inventors: Ji Soo HAN, Daejeon (KR); Jung Min SEO, Daejeon (KR); Jong Hyeok LEE, Daejeon (KR); Jong Chan IM, Daejeon (KR)

(21) Appl. No.: 19/386,100

(22) Filed: Nov. 11, 2025

(30) Foreign Application Priority Data
Nov. 18, 2024 (KR) 10-2024-0164305

(51) Int. Cl. G01R 31/392; G01R 31/388; H01M 10/44

(52) U.S. Cl. CPC G01R 31/392; G01R 31/388; H01M 10/441

(57) ABSTRACT

Proposed are a method and an apparatus for sorting out defective battery cells. The method includes performing constant voltage (CV) charging on a plurality of battery cells, measuring constant voltage charging capacity and constant voltage charging time of the plurality of battery cells in a constant voltage charging section, calculating a constant voltage charge value by dividing the constant voltage charging capacity by the constant voltage charging time measured in the constant voltage charging section for each of the battery cells, measuring an open circuit voltage of the plurality of battery cells after completion of the CV charging, and sorting out defective battery cells on the basis of the calculated constant voltage charge values and the measured open circuit voltages.

### CROSS REFERENCE TO RELATED APPLICATION

The present application claims priority to Korean Patent Application No. 10-2024-0164305, filed Nov. 18, 2024, the entire contents of which is incorporated herein for all purposes by this reference.

### TECHNICAL FIELD

The present disclosure relates to a method and an apparatus for sorting out defective battery cells.

### BACKGROUND

In general, lithium batteries, more specifically lithium-ion batteries, are rechargeable power sources widely used in portable electronics as well as electric and hybrid vehicles and energy storage systems.

Lithium battery manufacturing involves: forming an electrode assembly consisting of a positive electrode, a negative electrode, and a separator; placing the electrode assembly in a battery casing; and injecting an electrolyte into the electrode assembly.

A newly assembled lithium battery may appear functional but is incapable of performing its intended function until the battery receives a proper charge. Thus, by having the battery undergo specific initial charge/discharge cycles to activate its internal components, electrical properties can be imparted and the battery can function as a battery. This initial electrical activation of a battery after assembly is called formation. In addition, inspections are conducted during the formation process to detect or sort out defective batteries.

The formation process is crucial, but also one of the most time-consuming steps in lithium battery manufacturing. Therefore, methods to reduce battery formation process time are being explored. In other words, reducing formation process time can reduce both time and costs.

### SUMMARY

According to an aspect of the present disclosure, there is provide a method and an apparatus for sorting out defective battery cells, which identify defects in battery cells by using constant voltage (CV) charging during the formation (CHG) phase of the entire formation process.

According to an aspect of the present disclosure, there is provide a method and an apparatus for sorting out defective battery cells, which improve selectivity in detecting defective battery cells.

A method and an apparatus for sorting out defective battery cells according to an aspect of the present disclosure can be widely applied to green technology fields such as electric vehicles, battery charging stations, and solar and wind power generation using batteries.

A method and an apparatus for sorting out defective battery cells according to an aspect of the present disclosure can be applied to the manufacturing process of secondary batteries used in eco-friendly electric vehicles, hybrid vehicles, etc., to curb climate change by mitigating air pollution and greenhouse gas emissions.

A method for sorting out defective battery cells according to an aspect of the present disclosure includes: performing constant voltage (CV) charging on a plurality of battery cells; measuring constant voltage charging capacity and constant voltage charging time of the plurality of battery cells in a constant voltage charging section; calculating a constant voltage charge value by dividing the constant voltage charging capacity by the constant voltage charging time measured in the constant voltage charging section for each of the battery cells; measuring an open circuit voltage of the plurality of battery cells after completion of the CV charging; and sorting out defective battery cells on the basis of the calculated constant voltage charge values and the measured open circuit voltages.

According to an embodiment, the constant voltage charging section may be a section in which state of charge (SOC) of the plurality of battery cells is between 70% and 100%.

According to an embodiment, the sorting out of the defective battery cells on the basis of the calculated constant voltage charge values and the measured open circuit voltages may include: loading a pre-saved trend line showing a relationship between the open circuit voltage and the constant voltage charge value of the plurality of battery cells; calculating a trend value for the plurality of battery cells by inputting the open circuit voltage measured in the measuring of the open circuit voltage into the trend line; calculating a trend deviation value of the plurality of battery cells by subtracting the calculated trend value from the calculated constant voltage charge value; and determining a battery cell as defective when the calculated trend deviation value of the battery cell is outside a preset range.

According to an embodiment, in the determining a battery cell as defective when the calculated trend deviation value of the battery cell is outside the preset range, in case that the calculated trend deviation value exceeds a preset upper limit or falls below a preset lower limit, the battery cell may be determined to be defective.

According to an embodiment, the trend line may be as shown in Equation 1 below, and the trend value may be calculated by inputting the open circuit voltage measured in the measuring of the open circuit voltage into x in Equation 1 below.

$$y = ax + b \qquad ( Equation 1 )$$

y represents the trend line, x represents the open circuit voltage of the battery cell, a represents a slope of the trend line, and b represents a y-intercept of the trend line.

According to an embodiment, the sorting out of defective battery cells on the basis of the calculated constant voltage charge values and the measured open circuit voltages may include visualizing in which the measured open circuit voltage of the plurality of battery cells is designated as an X-axis value, the calculated trend deviation value of the plurality of battery cells is designated as a Y-axis value, and the calculated trend deviation values of the battery cells are displayed in dot form on a graph of X and Y axes.

According to an embodiment, the method may further include generating a trend line using the constant voltage charge value and the open circuit voltage of the plurality of battery cells, wherein the generating of the trend line may include: performing constant voltage (CV) charging on the plurality of battery cells; measuring the constant voltage charging capacity and the constant voltage charging time of the plurality of battery cells in the constant voltage charging section; calculating the constant voltage charge value by dividing the constant voltage charging capacity by the constant voltage charging time measured in the constant voltage charging section for each of the battery cells; measuring the open circuit voltage of the plurality of battery cells after completion of the CV charging; and calculating the trend line showing a relationship between the constant voltage charge value and the open circuit voltage of the plurality of battery cells on a graph where the constant voltage charge value is on a Y-axis and the open circuit voltage is on an X-axis.

An apparatus for sorting out defective battery cells according to an aspect of the present disclosure includes: a charger configured for performing constant voltage (CV) charging for a plurality of battery cells; a first measurement device configured to measure constant voltage charging capacity and constant voltage charging time of the plurality of battery cells charged by means of the charger in a constant voltage charging section; a second measurement device configured to measure an open circuit voltage of the plurality of battery cells after completion of the CV charging; and a controller configured to calculate a constant voltage charge value by dividing the constant voltage charging capacity by the constant voltage charging time of the plurality of battery cells measured by means of the first measurement device in the constant voltage charging section, and to sort out the defective battery cells on the basis of the calculated constant voltage charge value and the open circuit voltage measured by means of the second measurement device.

According to an embodiment, the constant voltage charging section may be a section in which state of charge (SOC) of the plurality of battery cells is between 70% and 100%.

According to an embodiment, the controller may calculate the constant voltage charge value by dividing the constant voltage charging capacity by the constant voltage charging time measured in the constant voltage charging section for each of the battery cells, may calculate a trend value for the plurality of battery cells by inputting the open circuit voltage measured after completion of the CV charging into a trend line, may calculate a trend deviation value of the plurality of battery cells by subtracting the trend value from the constant voltage charge value, and may compare the calculated trend deviation value to determine a battery cell as defective in case that the trend deviation value of the battery cell is outside a preset range.

According to an embodiment, the controller may determines a battery cell to be defective in case that the trend deviation value exceeds a preset upper limit or falls below a preset lower limit.

According to an embodiment, the trend line may be as shown in Equation 1 below, and the trend value may be calculated by inputting the open circuit voltage measured after completion of the CV charging is completed into x in Equation 1 below.

$$y = ax + b \qquad ( Equation 1 )$$

y represents the trend line, x represents the open circuit voltage of the battery cell, a represents a slope of the trend line, and b represents a y-intercept of the trend line.

According to an embodiment, the controller may designate the measured open circuit voltage of the plurality of battery cells as an X-axis value, may designate the calculated trend deviation value of the plurality of battery cells as a Y-axis value, and may visualize the calculated trend deviation values of the battery cells by displaying the calculated trend deviation values in dot form on a graph of X and Y axes.

According to an embodiment, the controller may generate the trend line by, may performing constant voltage charging on the plurality of battery cells, may measuring the constant voltage charging capacity and the constant voltage charging time of the plurality of battery cells in the constant voltage charging section, may calculating the constant voltage charge value by dividing the constant voltage charging capacity by the constant voltage charging time measured in the constant voltage charging section for each of the battery cells, may measuring the open circuit voltage of the plurality of battery cells after completion of the CV charging, and may calculating the trend line showing a relationship between the constant voltage charge value and the open circuit voltage of the plurality of battery cells on a graph where the constant voltage charge value is on a Y-axis and the open circuit voltage is on an X-axis.

The features and advantages of the present disclosure will become more apparent from the following detailed description based on the accompanying drawings.

Prior to this, terms or words used in this specification and claims should not be construed in their usual, dictionary meaning, and should be interpreted with meaning and concept consistent with the technical idea of the present disclosure on the basis of the principle that the inventor can define terminology appropriately to explain his or her invention in the best way possible.

According to an embodiment of the present disclosure, defective battery cells can be identified using constant voltage (CV) charging during the formation (CHG) phase of the entire formation process.

According to an embodiment of the present disclosure, it is possible to improve selectivity in detecting defective battery cells.

According to an embodiment of the present disclosure, it is possible to reduce the overall time required for the formation process, and lower the manufacturing costs of battery cells by shortening the formation process.

### BRIEF DESCRIPTION OF THE DRAWINGS

The above and other objectives, features, and other advantages of the present disclosure will be more clearly understood from the following detailed description when taken in conjunction with the accompanying drawings, in which:

FIG. 1 is a view showing a method for sorting out defective battery cells according to an embodiment;

FIG. 2 is a view showing an apparatus for performing a method for sorting out defective battery cells according to an embodiment;

FIG. 3 is a view showing a formation process for a method for sorting out defective battery cells according to an embodiment;

FIG. 4 is a view showing a conventional formation process in contrast to a formation process for a method for sorting out defective battery cells according to an embodiment;

FIG. 5 is a view showing a defect sorting step in a method for sorting out defective battery cells according to an embodiment;

FIG. 6 is a view showing a defect sorting step including a visualization step in a method for sorting out defective battery cells according to an embodiment;

FIG. 7 is a view showing visual processing including a trend line in a method for sorting out defective battery cells according to an embodiment;

FIG. 8 is a view showing visual processing of trend deviation values in a method for sorting out defective battery cells according to an embodiment;

FIG. 9 is a view showing a method for sorting out defective battery cells, including a trend line generation step, according to an embodiment;

FIG. 10 is a view showing a trend line generation step in a method for sorting out defective battery cells according to an embodiment; and

FIG. 11 is a view showing an apparatus for sorting out defective battery cells according to an embodiment.

### DETAILED DESCRIPTION

Hereinafter, the present disclosure will be described in detail (with reference to the attached drawings). However, this is merely exemplary and the present disclosure is not limited to the specific embodiments described as examples.

The drawings may be schematic or exaggerated for the purpose of illustrating the embodiments.

In this document, expressions such as “have”, “may have”, “include”, or “may include” refer to the presence of the corresponding feature (e.g., a numerical value, function, operation, or component such as a part), and do not exclude the presence of additional features.

Hereinafter, an embodiment of the present disclosure will be described in detail with reference to the attached drawings.

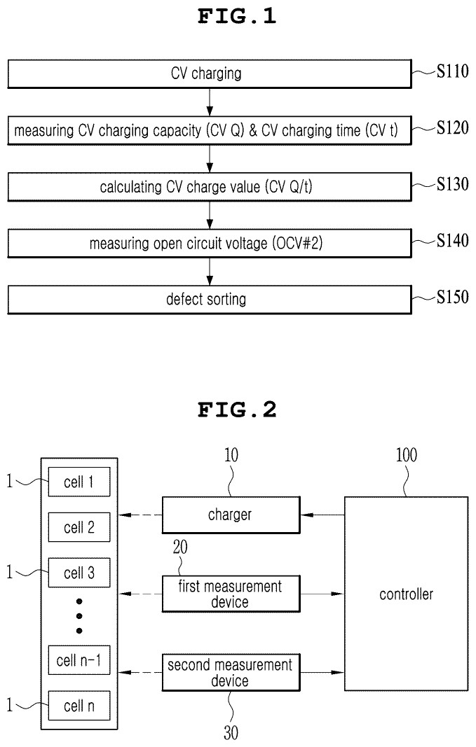

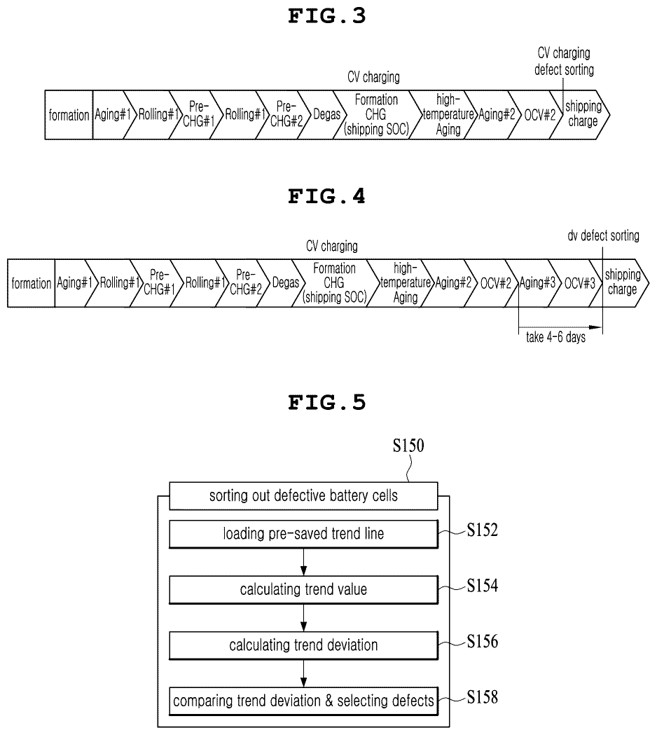

FIG. 1 is a view showing a method for sorting out defective battery cells according to an embodiment; FIG. 2 is a view showing an apparatus for performing a method for sorting out defective battery cells according to an embodiment; FIG. 3 is a view showing a formation process for a method for sorting out defective battery cells according to an embodiment; and FIG. 4 is a view showing a conventional formation process in contrast to a formation process for a method for sorting out defective battery cells according to an embodiment.

Referring to FIGS. 1 and 2, a method for sorting out defective battery cells according to the present disclosure may include: performing S110 constant voltage (CV) charging on a plurality of battery cells 1; measuring S120 constant voltage charging capacity CV Q and constant voltage charging time CV t of the battery cells 1 in a constant voltage (CV) charging section; calculating S130 a constant voltage charge value CV Q/t by dividing the constant voltage charging capacity CV Q for each of the battery cells measured in the constant voltage (CV) charging section by the constant voltage charging time CV t; measuring S140 an open circuit voltage OCV#2 of the plurality of battery cells 1 after completion of the CV charging; and sorting out S150 defective battery cells 1 on the basis of the calculated constant voltage charge value CV Q/t and the measured open circuit voltage OCV#2.

Performing S110 constant voltage (CV) charging on a plurality of battery cells 1 is a step of charging the plurality of battery cells 1 while maintaining a constant target voltage for each of the battery cells 1. Constant voltage (CV) charging may be performed on the plurality of battery cells 1 by means of a charger 10. In addition, as illustrated in FIG. 3, constant voltage (CV) charging may be performed during the formation phase of the entire formation process in battery manufacturing. Constant voltage (CV) charging may be performed for the battery cells 1 that have completed the pre-charging phase of the formation process. Constant voltage (CV) charging may be performed in a section where the state of charge (SOC) of a battery cell 1 exceeds a certain range.

Pre-charging in the formation process may be the initial charge given to a battery cell 1 after injecting electrolyte into the assembled battery cell 1. Pre-charging may be a process that initiates the formation of a solid electrolyte interphase (SEI) layer on the surface of a negative electrode. Pre-charging may bring a battery cell 1 to an approximately 20% SOC. Pre-charging may be performed more than once. FIG. 3 shows that pre-charging is performed twice, as pre-charging 1 Pre-CHG#1 and pre-charging 2 Pre-CHG#2.

The formation phase of the formation process may be a step to impart electrical properties, such as growing and stabilizing the SEI layer by performing charging after pre-charging. The formation phase may take the SOC of a battery cell 1 to 100%. In the formation phase, charging and discharging of a battery cell 1 may be repeated.

As such, in the present disclosure, by using the constant voltage (CV) charging of the battery cell 1 as a prerequisite for sorting out defective battery cells, it is possible to provide greater advantage in sorting out defective battery cells 1. Since an electric current is being applied to a battery cell 1 during constant voltage (CV) charging, leakage current may be detected better when a defect is caused by damage or foreign substances. In contrast, in the conventional method of low-voltage sorting that is mainly used in formation, an open circuit voltage of a battery cell 1 is measured two to three times after completing the formation phase, as shown in FIG. 4, and the voltage change dV over time is calculated based on the measurement results to sort out defective battery cells 1. The conventional low-voltage sorting method measures the open circuit voltage of a non-operating battery cell 1, making detection of leakage current as well as finding the cause of leakage current difficult because the battery cell 1 is not in an actual use state. As a result, selectivity in detecting defective battery cells 1 may be reduced and incorrect determinations may be made. FIG. 4 shows that the open circuit voltage is measured at least twice, including OCV#2 and OCV#3, to calculate a time-dependent voltage change dV of a battery cell 1.

Measuring S120 constant voltage charging capacity CV Q and constant voltage charging time CV t of the battery cells 1 in a constant voltage (CV) charging section is a step of measuring the constant voltage charging capacity CV Q gained and the constant voltage charging time CV t taken in the constant voltage (CV) charging section for each battery cell 1. The constant voltage charging capacity CV Q gained and the constant voltage charging time CV t taken during constant voltage (CV) charging of the battery cells 1 may be measured by means of a first measurement device 20. In case that a battery cell 1 is defective, a leakage current may occur within the battery cell 1 due to a micro-short circuit, and thus the constant voltage charging time CV t may become longer. At this time, the constant voltage (CV) charging section may be a section in which the SOC of the plurality of battery cells 1 is between 70% and 100%. The constant voltage (CV) charging section may be a section in which the SOC of the plurality of battery cells 1 is between 80% and 100%. The constant voltage (CV) charging section may be a section in which the SOC of the plurality of battery cells 1 is between 90% and 100%.

In this way, the constant voltage charging capacity CV Q and constant voltage charging time CV t measured for each of the battery cells 1 may be used as basic data for determining whether each battery cell 1 is defective.

In the step of calculating S130 a constant voltage charge value CV Q/t for each of the battery cells 1, a constant voltage charge value CV Q/t may be calculated to be used as data for determining whether each battery cell 1 is defective on the basis of the constant voltage charging capacity CV Q and the constant voltage charging time CV t of the battery cells 1 measured in the constant voltage (CV) charging section. A controller 100 that receives measurement data from the first measurement device 20 may calculate the constant voltage charge value CV Q/t.

In the step of measuring S140 the open circuit voltage OCV#2 of the plurality of battery cells 1 after completion of the CV charging, referring to FIG. 3, the open circuit voltage OCV#2 may be measured for each of the battery cells 1 that has completed aging after constant voltage (CV) charging is performed in the formation phase of the formation process. At this time, aging is a process of storing a battery cell for a predetermined period of time while maintaining a predetermined temperature and humidity to ensure sufficient impregnation and dispersion of the electrolyte in the battery cell 1 in the formation process, and may be a process of stabilizing the electrical characteristics of the battery cell. The aging phase may include high-temperature aging and aging #2 as illustrated in FIG. 3. In the present disclosure, the open circuit voltage OCV#2, which is a value measured when the electrical characteristics of a battery cell are more stable compared to the values measured during constant voltage (CV) charging may be used as data to improve the ability to sort defective battery cells 1. In the step of measuring S140 the open circuit voltage OCV#2 of the battery cells 1 after completion of the CV charging, a second measurement device 30 may be used for the measurement.

Sorting out S150 defective battery cells 1 on the basis of the calculated constant voltage charge value CV Q/t and the measured open circuit voltage OCV#2 is a step of identifying the data trend according to the relationship between the calculated constant voltage charge value CV Q/t and the measured open circuit voltage OCV#2 and determining whether there is a battery cell 1 defect on the basis of the data trend. The controller 100 that receives measurement data from the first measurement device 20 and the second measurement device 30 may identify a defective battery cell 1 on the basis of the calculated constant voltage charge value CV Q/t and the measured open circuit voltage OCV#2. In the present disclosure, by utilizing the data trend identified according to the relationship between the calculated constant voltage charge value CV Q/t and the measured open circuit voltage OCV#2, selectivity in detecting defective battery cells 1 may be improved.

As shown in FIG. 3, the step of sorting out S150 defective battery cells 1 on the basis of the calculated constant voltage charge value CV Q/t and the measured open circuit voltage OCV#2 may be performed in the process of measuring the open circuit voltage OCV#2 of a battery cell 1 that has completed the formation phase of the formation process. Due to this, in contrast to the conventional formation process shown in FIG. 4, the aging Aging#3 and open circuit voltage OCV#3 phases at the end of the process shown in FIG. 4 may be eliminated in the present disclosure. In the conventional formation process shown in FIG. 4, the aging Aging#3 and open circuit voltage OCV#3 phases typically take 4 to 6 days. That is, in the present disclosure, the total period required for the formation process may be shortened by 4 to 6 days.

Thus, in the present disclosure, since the constant voltage (CV) charging of a battery cell 1 during the formation phase during the formation process is used as a basic prerequisite, it is possible to more easily sort out defective battery cells 1. Selectivity in detecting defects in the battery cells 1 may be improved. In addition, the present disclosure may reduce the overall time required for the formation process and reduce the battery cell 1 manufacturing cost.

In the method for sorting out defective battery cells according to the present disclosure, in the step of measuring S120 the constant voltage charging capacity CV Q and constant voltage charging time CV t of the battery cells 1 in the constant voltage (CV) charging section, a current value may also be measured. The current measurement may be used to check whether constant voltage (CV) charging is being performed properly. Since current is supplied to the battery cells 1 during constant voltage (CV) charging, the current value may be measured. Due to this, the reliability of the constant voltage charging capacity CV Q and the constant voltage charging time CV t, and the constant voltage charge value CV Q/t calculated therefrom may be increased. The reliability of sorting out defective battery cells 1 may be increased.

FIG. 5 is a view showing a defect sorting step in a method for sorting out defective battery cells according to an embodiment.

Referring to FIG. 5, in the method for sorting out defective battery cells according to the present disclosure, the step of sorting out S150 defective battery cells 1 on the basis of the calculated constant voltage charge value CV Q/t and the measured open circuit voltage OCV#2 may include: loading S152 a pre-saved trend line showing the relationship between the open circuit voltage OCV#2 and the constant voltage charge value CV Q/t of a plurality of battery cells 1; calculating S154 a trend value for the plurality of battery cells 1 by inputting the open circuit voltage OCV#2 measured in the step of measuring S140 the open circuit voltage OCV#2 into the trend line; calculating S156 trend deviation value of the plurality of battery cells 1 by subtracting the calculated trend value from the calculated constant voltage charge value CV Q/t; and determining S158 a battery cell 1 as defective when the calculated trend deviation value of the battery cell 1 is outside the preset range.

In the step of loading S152 a pre-saved trend line showing the relationship between the open circuit voltage OCV#2 and the constant voltage charge value CV Q/t of battery cells 1, trend line data stored in the controller 100 may be retrieved. The trend line may be created and stored in advance.

In the step of calculating S154 a trend value for the plurality of battery cells 1 by inputting the open circuit voltage OCV#2 measured in the step of measuring S140 the open circuit voltage OCV#2 into the trend line, by inputting the measured open circuit voltage OCV#2 value for each battery cell 1 into the trend line in the loading state, a trend value for each battery cell 1 may be calculated. The trend value may be calculated in the controller 100.

In the present disclosure, the relationship between the trend line and the trend value calculated therefrom is explained as follows.

The trend line is as shown in Equation 1 below, and the trend value may be calculated by inputting the open circuit voltage OCV#2 measured in the step of measuring S140 the open circuit voltage into x in Equation 1 below.

$$y = ax + b \qquad ( Equation 1 )$$

y represents the trend line, x represents the open circuit voltage OCV#2 of the battery cell 1, a represents the slope of the trend line, and b represents the y-intercept of the trend line.

That is, the trend line may be a single connection line that can represent trend values produced for individual battery cells 1. The trend line may have a slope.

Calculating S156 trend deviation value of the plurality of battery cells 1 by subtracting the calculated trend value from the calculated constant voltage charge value CV Q/t is a step of calculating the trend deviation value of the plurality of battery cells 1 using the trend values of the battery cells 1 calculated from Equation 1. The trend deviation value may be calculated by the controller 100. The trend deviation value may be a positive (+) value greater than “0” or a negative (−) value less than “0”.

In the step of determining S158 a battery cell 1 as defective when the calculated trend deviation value of the battery cell 1 is outside the preset range, a battery cell 1 may be selected by determining whether the battery cell 1 is defective among the battery cells 1.

In the step of determining S158 a battery cell 1 as defective when the calculated trend deviation value of the battery cell 1 is outside the preset range, in case that the calculated trend deviation value deviates from the upper or lower limit of the preset range, the corresponding battery cell 1 may be determined as a faulty product. Specifically, In case that trend deviation value exceeds a preset upper limit or falls below a preset lower limit, the corresponding battery cell 1 may be determined as s faulty product. In case that the calculated trend deviation value is within the upper and lower limits of the preset range, the corresponding battery cell 1 may be determined to be a good product.

Therefore, in the present disclosure, by quantifying the trend of the plurality of battery cells 1 on the basis of the constant voltage charge value CV Q/t and open circuit voltage OCV#2, selectivity in detecting defective battery cells 1 may be improved. According to the present disclosure, selectivity may be improved compared to the conventional low-voltage sorting method that measures only the open circuit voltage multiple times and then calculates the voltage change dV over time to sort defective battery cells. The present disclosure enables sorting out of defective battery cells that are difficult to identify with the conventional low-voltage sorting method that relies on time-dependent voltage changes dV.

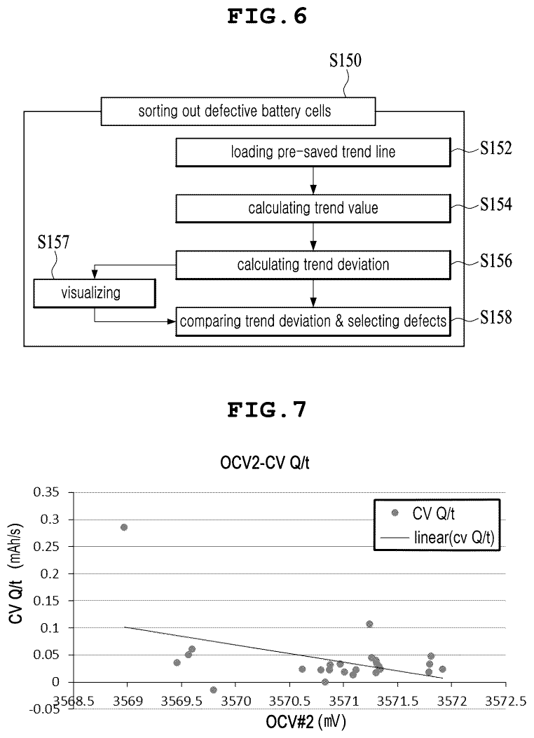

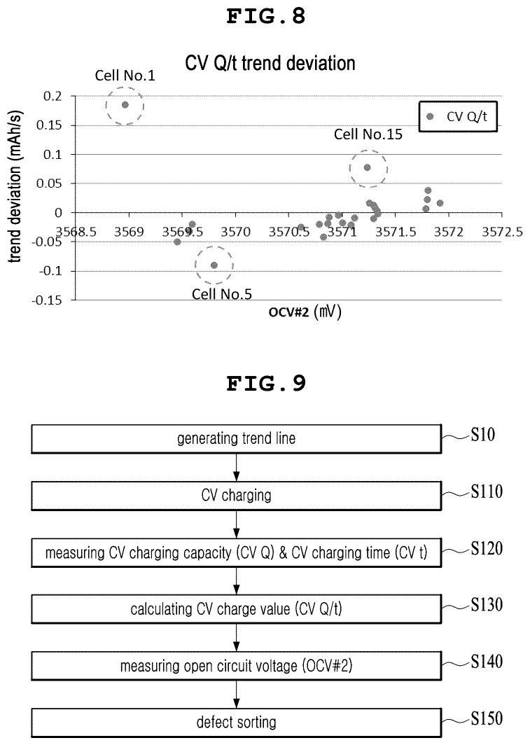

FIG. 6 is a view showing a defect sorting step including a visualization step in a method for sorting out defective battery cells according to an embodiment; FIG. 7 is a view showing visual processing including a trend line in a method for sorting out defective battery cells according to an embodiment; and FIG. 8 is a view showing visual processing of trend deviation values in a method for sorting out defective battery cells according to an embodiment.

Referring to FIG. 6, in the method for sorting out defective battery cells according to the present disclosure, the step of sorting out S150 defective battery cells 1 on the basis of the calculated constant voltage charge value CV Q/t and the measured open circuit voltage OCV#2 may further include: visualizing S157 in which the measured open circuit voltage OCV#2 of the plurality of battery cells 1 is designated as the X-axis value, the calculated trend deviation value of the plurality of battery cells 1 is designated as the Y-axis value, and the calculated trend deviation values of the battery cells 1 are displayed in dot form on the graph of the X and Y axes.

The step of visualizing S157 may be interposed between: calculating S156 the trend deviation value of the plurality of battery cells 1 by subtracting the calculated trend value from the calculated constant voltage charge value CV Q/t; and selecting S158 a battery cell 1 as defective when the calculated trend deviation value of the battery cell 1 is outside the preset range.

The step of visualizing S157 may provide the advantage of easily sorting out and identifying defective battery cells 1 visually by displaying the battery cells 1 in a graph on a computer screen using digitized data. The step of visualizing S157 may be performed by the controller 100.

The step of visualizing S157 may include a first visualizing in which the numerical data of the calculated constant voltage charge value CV Q/t, the measured open circuit voltage OCV#2, and the trend line that produces the trend value are visualized on a graph. The first visualizing step may be omitted.

The step of visualizing S157 may include a second visualizing in which the numerical data of the calculated constant voltage charge value CV Q/t, the measured open circuit voltage OCV#2, and the trend deviation value are visualized on a graph. The second visualizing step may represent the step of visualizing S157. On the basis of trend deviation value of the plurality of battery cells 1 displayed on the graph through the second visualizing step, a defective battery cell may be identified. In case that a trend deviation value of a battery cell 1 falls outside a preset range, the corresponding battery cell 1 may be determined to be defective.

FIG. 7 is a view showing the first visualizing step. FIG. 7 shows that the measured open circuit voltage OCV#2 of the plurality of battery cells 1 is designated as the X-axis value, whereas the calculated constant voltage charge value CV Q/t of the plurality of battery cells 1 is designated as the Y-axis value, and the calculated constant voltage charge values CV Q/t of the battery cells 1 are displayed in dot form on a graph of the X and Y-axis with the trend line displayed. The open circuit voltages OCV#2 shown on the X-axis of the graph are in a unit of “mV”, and the constant voltage charge values CV Q/t shown on the Y-axis are in a unit of “mAh/s”.

In addition, FIG. 8 is a view showing the second visualizing step. FIG. 8 shows that the measured open circuit voltage OCV#2 of the plurality of battery cells 1 is designated as the X-axis value, whereas the calculated trend deviation value of the plurality of battery cells 1 is designated as the Y-axis value, and the calculated trend deviation values of the battery cells 1 are displayed in dot form on a graph of the X and Y-axis. The open circuit voltages OCV#2 shown on the X-axis of the graph are in a unit of “mV”, and the trend deviation values shown on the Y-axis are in a unit of “mAh/s”.

At this time, in the step of selecting S158 a battery cell 1 as defective when the calculated trend deviation value of the battery cell 1 is outside the preset range, it is possible to easily check visually whether the trend deviation value of a battery cell 1 is outside the preset range.

For example, when the preset range is a value of “±0.1”, in FIG. 8, it is easy to identify a battery cell (1) whose trend deviation value falls outside the preset range. It is easy to identify that the battery cell with cell number 1 is defective because the trend deviation value thereof falls significantly outside the preset range. In addition, in FIG. 8, it can be confirmed that the battery cells corresponding to cell numbers 5 and 15 are slightly off the zero point, but the trend deviation values are within the preset range. In this case, the corresponding battery cells 1 may be selected as good products. In addition, the corresponding battery cells 1 located close to the zero points of the X-axis and Y-axis may be considered good products whose trend deviation values do not exceed the preset range.

In the step of selecting S158 a battery cell 1 as defective when the calculated trend deviation value of the battery cell 1 is outside the preset range, the preset range, that is, the upper and lower limits, may vary depending on the type and specifications of the battery cells 1.

Therefore, in the present disclosure, due to the step of visualizing S157, it is possible to easily sort and identify defective battery cells 1 visually, and to reduce or prevent errors resulting from the selection of defective battery cells 1.

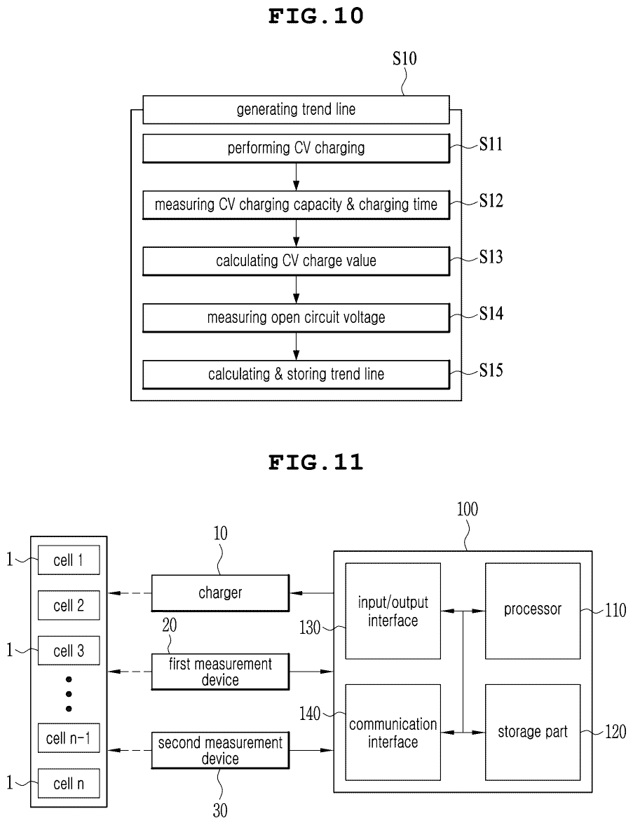

FIG. 9 is a view showing a method for sorting out defective battery cells, including a trend line generation step, according to an embodiment; and FIG. 10 is a view showing a trend line generation step in a method for sorting out defective battery cells according to an embodiment.

Referring to FIGS. 9 and 10, the method for sorting out defective battery cells according to the present disclosure may further include: generating S10 a trend line using the constant voltage charge value CV Q/t and open circuit voltage OCV#2 of the plurality of battery cells 1. The step of generating S10 a trend line may include: performing S11 constant voltage (CV) charging on the battery cells 1; measuring S12 constant voltage charging capacity CV Q and constant voltage charging time CV t of the plurality of battery cells 1 in the constant voltage (CV) charging section; calculating S13 the constant voltage charge value CV Q/t by dividing the constant voltage charging capacity CV Q for each of the battery cells 1 measured in the constant voltage (CV) charging section by the constant voltage charging time CV t; measuring S14 the open circuit voltage OCV#2 of the plurality of battery cells 1 after completion of the CV charging; and calculating S15 the trend line showing the relationship between the constant voltage charge value CV Q/t and the open circuit voltage OCV#2 of the plurality of battery cells 1 on a graph where the constant voltage charge value CV Q/t is on the Y-axis and the open circuit voltage OCV#2 is on the X-axis.

Generating S10 a trend line using the constant voltage charge value CV Q/t and open circuit voltage OCV#2 of the plurality of battery cells 1 is a step for datafication of a trend line by performing a test in advance. As shown in FIG. 2, an apparatus for sorting out defective battery cells including the charger 10, the first measurement device 20, the second measurement device 30, and the controller 100 may be used.

Calculating S15 the trend line may include a process of storing the calculated trend line.

In addition, in the method for sorting out defective battery cells, the plurality of battery cells 1 may be one of a pouch cell, a prismatic cell, and a cylindrical cell. The present disclosure may be applied to the sorting out of defective battery cells regardless of the shape of the battery cells.

FIG. 11 is a view showing an apparatus for sorting out defective battery cells according to an embodiment.

Referring to FIG. 11, the apparatus for sorting out defective battery cells according to the present disclosure may include: a charger 10 configured for performing constant voltage (CV) charging for a plurality of battery cells 1; a first measurement device 20 configured to measure constant voltage charging capacity CV Q and constant voltage charging time CV t of the plurality of battery cells 1 charged by means of the charger 10 in a constant voltage (CV) charging section; a second measurement device 30 configured to measure an open circuit voltage OCV#2 of the plurality of battery cells 1 after completion of the CV charging; and a controller 100 configured to calculate a constant voltage charge value CV Q/t by dividing the constant voltage charging capacity CV Q by the constant voltage charging time CV t of the plurality of battery cells 1 measured in the constant voltage (CV) charging section by means of the first measurement device 20, and to sort out defective battery cells 1 on the basis of the calculated constant voltage charge value CV Q/t and the open circuit voltage OCV#2 measured by means of the second measurement device 30.

The charger 10 may charge the plurality of battery cells 1 while maintaining a constant target voltage for each of the battery cells 1. Constant voltage (CV) charging may be performed during the formation phase of the entire formation process in battery manufacturing. Constant voltage (CV) charging may be performed for the battery cells 1 that have completed the pre-charging phase of the formation process. Constant voltage (CV) charging may be performed in a section where the state of charge (SOC) of a battery cell 1 exceeds a certain range.

The first measurement device 20 may measure the constant voltage charging capacity CV Q gained and the constant voltage charging time CV t taken in the constant voltage (CV) charging section for each battery cell 1. At this time, the constant voltage (CV) charging section may be a section in which the SOC of the plurality of battery cells 1 is between 70% and 100%. The constant voltage (CV) charging section may be a section in which the SOC of the plurality of battery cells 1 is between 80% and 100%. The constant voltage (CV) charging section may be a section in which the SOC of the plurality of battery cells 1 is between 90% and 100%.

The second measurement device 30 may measure the open circuit voltage OCV#2 of each of the battery cells 1 that has completed aging after constant voltage (CV) charging is performed in the formation phase of the formation process.

The controller 100 may determine whether each battery cell 1 is defective on the basis of the constant voltage charge value CV Q/t calculated by using the constant voltage charging capacity CV Q and the constant voltage charging time CV t of the battery cells 1 measured by the first measurement device 20 in the constant voltage (CV) charging section, and the open circuit voltage OCV#2 measured by the second measurement device 30.

Referring to FIG. 11, the controller 100 may include a processor 110 and a storage part 120. The processor 110 may read and execute program codes and data stored in the storage part 120. The processor 110 and the storage part 120 may be connected to enable data transmission and reception. The storage part 120 may store program codes and data written to perform battery cell 1 defect sorting. The storage part 120 may store trend line data indicating the relationship between the open circuit voltage OCV#2 and the constant voltage charge value CV Q/t of the plurality of battery cells 1.

The controller 100 may further include an input/output interface 130 or a communication interface 140. The input/output interface 130 may include a display for providing information visually representing data to a user, or a display device such as a notification light or speaker for notifying the user of a defect in the battery cells 1. The input/output interface 130 may include a touchpad, keyboard, mouse, or other input device for the user to input commands or data.

The communication interface 140 may transmit and receive data or commands to and from the charger 10, the first measurement device 20, and the second measurement device 30. The communication interface 140 may be used to notify the user of which battery cell 1 has a defect. The communication interface 140 may utilize wired communication methods such as LAN, WAN, and Ethernet, mobile communication methods such as 5G and LTE, and short-range wireless communication methods such as Wi-Fi, Bluetooth, and Zigbee.

The controller 100 may control the charger 10 to perform constant voltage (CV) charging on the plurality of battery cells 1. The controller 100 may receive the constant voltage charging capacity CV Q and constant voltage charging time CV t of the plurality of battery cells 1 measured by the first measurement device 20 in the constant voltage (CV) charging section. The controller 100 may receive the open circuit voltage OCV#2 of the plurality of battery cells 1 measured by the second measurement device 30 after the constant voltage (CV) charging is completed.

The controller 100 may calculate the constant voltage charge value CV Q/t by dividing the constant voltage charging capacity CV Q of the plurality of battery cells 1 measured in the constant voltage (CV) charging section by the constant voltage charging time CV t, calculate the trend value for the plurality of battery cells 1 by inputting the open circuit voltage OCV#2 measured after the constant voltage (CV) charging is completed into the trend line, calculate the trend deviation value of the plurality of battery cells 1 by subtracting the trend value from the constant voltage charge value CV Q/t, and compare the calculated trend deviation value to select a battery cell 1 as defective if the trend deviation value of the battery cell 1 is outside the preset range.

To be specific, the controller 100 may calculate the constant voltage charge value CV Q/t using the measurement data of the constant voltage charging capacity CV Q and the constant voltage charging time CV t of the plurality of battery cells 1 measured in the constant voltage (CV) charging section. The controller 100 may calculate the constant voltage charge value CV Q/t by dividing the constant voltage charging capacity CV Q by the constant voltage charging time CV t.

The controller 100 may calculate the trend value for the plurality of battery cells 1 by inputting the open circuit voltage OCV#2 measured after the constant voltage (CV) charging is completed into the trend line.

The trend line is as shown in Equation 1 below, and the trend value may be calculated by inputting the open circuit voltage OCV#2 measured after the constant voltage charging is completed into x in Equation 1 below.

$$y = ax + b \qquad ( Equation 1 )$$

y represents the trend line, x represents the open circuit voltage of the battery cell, a represents the slope of the trend line, and b represents the y-intercept of the trend line.

The trend line may be data generated in advance and stored in the storage part 120. The trend line may represent the relationship between the constant voltage charge value CV Q/t and the open circuit voltage OCV#2 of the plurality of battery cells 1.

The open circuit voltage OCV#2 may be measured for each of the battery cells 1 that has completed aging after constant voltage (CV) charging is performed in the formation phase of the formation process. At this time, aging may include high-temperature aging and aging #2.

The controller 100 may calculate the trend value for each of the battery cells 1 using the trend line formula of Equation 1. The controller 100 may calculate the trend deviation value of the plurality of battery cells 1 by subtracting the trend value from the constant voltage charge value CV Q/t. The controller 100 may compare the trend deviation values calculated in this manner and determine, if the trend deviation value of a battery cell 1 falls outside a preset range, that the corresponding battery cell 1 is defective. The controller 100 may determine that the corresponding battery cell is defective if the trend deviation value falls outside the upper or lower limit of the preset range. Specifically, In case that trend deviation value exceeds a preset upper limit or falls below a preset lower limit, the corresponding battery cell 1 may be determined as s faulty product.

In addition, as shown in FIG. 8, the controller 100 may designate the measured open circuit voltage OCV#2 of the plurality of battery cells 1 as the X-axis value and designate the calculated trend deviation value of the plurality of battery cells 1 as the Y-axis value, and visualize the calculated trend deviation values of the battery cells 1 by displaying the calculated trend deviation values in dot form on a graph of the X and Y axes.

Meanwhile, the trend line described above may be data generated in advance and stored in the storage part 120. The trend line may be data that has been converted into data by performing a test in advance.

To this end, the controller 100 may generate a trend line by, performing constant voltage (CV) charging on the plurality of battery cells 1, measuring the constant voltage charging capacity CV Q and the constant voltage charging time CV t of the plurality of battery cells 1 in the constant voltage (CV) charging section, calculating the constant voltage charge value CV Q/t by dividing the constant voltage charging capacity CV Q by the constant voltage charging time CV t measured in the constant voltage (CV) charging section for each of the battery cells 1, measuring the open circuit voltage OCV#2 of the plurality of battery cells 1 after completion of the CV charging, and calculate the trend line showing the relationship between the constant voltage charge value CV Q/t and the open circuit voltage OCV#2 of the plurality of battery cells 1 on a graph where the constant voltage charge value CV Q/t is on the Y-axis and the open circuit voltage OCV#2 is on the X-axis. That is, through this process, a trend line represented by the Equation 1 described above may be created. The trend line creation step of FIG. 10 may be referenced.

The plurality of battery cells 1 may be one of a pouch cell, a prismatic cell, and a cylindrical cell. The present disclosure may be applied to the battery cell defect sorting regardless of the shape of the battery cells.

Therefore, according to the present disclosure, by utilizing constant voltage charging during the formation phase during the formation process, defective battery cells may be sorted out, and selectivity in detecting defective battery cells may be improved.

Above, the present disclosure has been described in detail through specific embodiments. The above description is merely an example of the application of the principles of the present disclosure, and other configurations may be included or replaced with other components without departing from the scope of the present disclosure.

What is claimed is:

1. A method for sorting out defective battery cells, the method comprising:
performing constant voltage (CV) charging on a plurality of battery cells;
measuring constant voltage charging capacity and constant voltage charging time of the plurality of battery cells in a constant voltage charging section;
calculating a constant voltage charge value by dividing the constant voltage charging capacity by the constant voltage charging time measured in the constant voltage charging section for each of the battery cells;
measuring an open circuit voltage of the plurality of battery cells after completion of the CV charging; and
sorting out defective battery cells on the basis of the calculated constant voltage charge values and the measured open circuit voltages.

2. The method of claim 1, wherein the constant voltage charging section is a section in which state of charge (SOC) of the plurality of battery cells is between 70% and 100%.

3. The method of claim 1, wherein the sorting out the defective battery cells on the basis of the calculated constant voltage charge values and the measured open circuit voltages comprises:
loading a pre-saved trend line showing a relationship between the open circuit voltage and the constant voltage charge value of the plurality of battery cells;
calculating a trend value for the plurality of battery cells by inputting the open circuit voltage measured in the measuring of the open circuit voltage into the trend line;
calculating a trend deviation value of the plurality of battery cells by subtracting the calculated trend value from the calculated constant voltage charge value; and
determining a battery cell as defective when the calculated trend deviation value of the battery cell is outside a preset range.

4. The method of claim 3, wherein the determining a battery cell as defective when the calculated trend deviation value of the battery cell is outside the preset range,
in case that the calculated trend deviation value exceeds a preset upper limit or falls below a preset lower limit, the battery cell is determined to be defective.

5. The method of claim 3, wherein the trend line is as shown in Equation 1 below, and
the trend value is calculated by inputting the open circuit voltage measured in the measuring of the open circuit voltage into x in Equation 1 below,
$$y = ax + b \qquad ( Equation 1 )$$
y represents the trend line, x represents the open circuit voltage of the battery cell, a represents a slope of the trend line, and b represents a y-intercept of the trend line.

6. The method of claim 3, wherein the sorting out of the defective battery cells on the basis of the calculated constant voltage charge values and the measured open circuit voltages comprises:
visualizing in which the measured open circuit voltage of the plurality of battery cells is designated as an X-axis value, the calculated trend deviation value of the plurality of battery cells is designated as a Y-axis value, and the calculated trend deviation values of the battery cells are displayed in dot form on a graph of X and Y axes.

7. The method of claim 1, further comprising:
generating a trend line using the constant voltage charge value and the open circuit voltage of the plurality of battery cells,
wherein the generating of the trend line comprises:
performing constant voltage (CV) charging on the plurality of battery cells;
measuring the constant voltage charging capacity and the constant voltage charging time of the plurality of battery cells in the constant voltage charging section;
calculating the constant voltage charge value by dividing the constant voltage charging capacity by the constant voltage charging time measured in the constant voltage charging section for each of the battery cells;
measuring the open circuit voltage of the plurality of battery cells after completion of the CV charging; and
calculating the trend line showing a relationship between the constant voltage charge value and the open circuit voltage of the plurality of battery cells on a graph where the constant voltage charge value is on a Y-axis and the open circuit voltage is on an X-axis.

8. An apparatus for sorting out defective battery cells, the apparatus comprising:
a charger configured for performing constant voltage (CV) charging for a plurality of battery cells;
a first measurement device configured to measure constant voltage charging capacity and constant voltage charging time of the plurality of battery cells charged by means of the charger in a constant voltage charging section;
a second measurement device configured to measure an open circuit voltage of the plurality of battery cells after completion of the CV charging; and
a controller configured to calculate a constant voltage charge value by dividing the constant voltage charging capacity by the constant voltage charging time of the plurality of battery cells measured by means of the first measurement device in the constant voltage charging section, and to sort out the defective battery cells on the basis of the calculated constant voltage charge value and the open circuit voltage measured by means of the second measurement device.

9. The apparatus of claim 8, wherein the constant voltage charging section is a section in which state of charge (SOC) of the plurality of battery cells is between 70% and 100%.

10. The apparatus of claim 8, wherein the controller calculates the constant voltage charge value by dividing the constant voltage charging capacity by the constant voltage charging time measured in the constant voltage charging section for each of the battery cells, calculates a trend value for the plurality of battery cells by inputting the open circuit voltage measured after completion of the CV charging into a trend line, calculates a trend deviation value of the plurality of battery cells by subtracting the trend value from the constant voltage charge value, and compares the calculated trend deviation value to determine a battery cell as defective in case that the trend deviation value of the battery cell is outside a preset range.

11. The apparatus of claim 10, wherein the controller determines a battery cell to be defective in case that the trend deviation value exceeds a preset upper limit or falls below a preset lower limit.

12. The apparatus of claim 10, wherein the trend line is as shown in Equation 1 below, and
the trend value is calculated by inputting the open circuit voltage measured after completion of the CV charging is completed into x in Equation 1 below,
$$y = ax + b \qquad ( Equation 1 )$$
y represents the trend line, x represents the open circuit voltage of the battery cell, a represents a slope of the trend line, and b represents a y-intercept of the trend line.

13. The apparatus of claim 10, wherein the controller designates the measured open circuit voltage of the plurality of battery cells as an X-axis value, designates the calculated trend deviation value of the plurality of battery cells as a Y-axis value, and visualizes the calculated trend deviation values of the battery cells by displaying the calculated trend deviation values in dot form on a graph of X and Y axes.

14. The apparatus of claim 10, wherein the controller generates the trend line by,
performing constant voltage charging on the plurality of battery cells, measuring the constant voltage charging capacity and the constant voltage charging time of the plurality of battery cells in the constant voltage charging section, calculating the constant voltage charge value by dividing the constant voltage charging capacity by the constant voltage charging time measured in the constant voltage charging section for each of the battery cells, measuring the open circuit voltage of the plurality of battery cells after completion of the CV charging, and calculating the trend line showing a relationship between the constant voltage charge value and the open circuit voltage of the plurality of battery cells on a graph where the constant voltage charge value is on a Y-axis and the open circuit voltage is on an X-axis.
